(19) United States
(12) Patent Application Publication
(10) Pub. No.: US 2025/0285703 A1
(43) Pub. Date: Sep. 11, 2025

(54) USE OF DYNAMIC BLOCKS FOR REPAIRS IN A MEMORY SYSTEM

(71) Applicant: Micron Technology, Inc., Boise, ID (US)

(72) Inventors: Chun Sum Yeung, San Jose, CA (US); Deping He, Boise, ID (US)

(21) Appl. No.: 19/052,035

(22) Filed: Feb. 12, 2025

Related U.S. Application Data
(60) Provisional application No. 63/561,641, filed on Mar. 5, 2024.

(51) Int. Cl. G11C 29/00; G11C 29/52

(52) U.S. Cl. CPC G11C 29/808; G11C 29/52; G11C 29/72

(57) ABSTRACT

Methods, systems, and devices for use of dynamic blocks for repairs in a memory system are described. A memory system may select, from a set of dynamic blocks, a subset of dynamic blocks as candidates for replacing other blocks. The memory system may determine whether a static block in a set of static blocks has satisfied a condition for replacement. The memory system may update, based on determining that the static block satisfies the condition for replacement, replacement information for tracking block replacements to indicate that a dynamic block in the subset of dynamic blocks is to be used instead of the static block for subsequent access operations.

### CROSS REFERENCE

The present Application for Patent claims priority to U.S. Patent Application No. 63/561,641 by Yeung et al., entitled “USE OF DYNAMIC BLOCKS FOR REPAIRS IN A MEMORY SYSTEM,” filed Mar. 5, 2024, which is assigned to the assignee hereof, and which is expressly incorporated by reference in its entirety herein.

### TECHNICAL FIELD

The following relates to one or more systems for memory, including use of dynamic blocks for repairs in a memory system.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states if disconnected from an external power source.

### BRIEF DESCRIPTION OF THE DRAWINGS

FIG. 1 shows an example of a system that supports use of dynamic blocks for repairs in a memory system in accordance with examples as disclosed herein.

FIG. 2 shows an example of a memory system that supports use of dynamic blocks for repairs in accordance with examples as disclosed herein.

FIG. 3 shows an example of memory dies that support use of dynamic blocks for repairs in a memory system in accordance with examples as disclosed herein.

FIG. 4 shows an example of a process flow that supports use of dynamic blocks for repairs in a memory system in accordance with examples as disclosed herein.

FIG. 5 shows a block diagram of a memory system that supports use of dynamic blocks for repairs in a memory system in accordance with examples as disclosed herein.

FIG. 6 shows a flowchart illustrating a method or methods that support use of dynamic blocks for repairs in a memory system in accordance with examples as disclosed herein.

### DETAILED DESCRIPTION

A memory system with memory blocks may use some of the blocks as static blocks and may use some of the blocks as dynamic blocks. A static block may refer to a block to which a single type of write operation is permitted, such as a single-level-cell (SLC) write operation which writes a single bit per cell. A dynamic block may refer to a block to which multiple types of write operations are permitted, such as an SLC write operation and a multi-bit write operation that writes multiple bits per cell. In some examples (e.g., to support repair procedures), a memory system may designate a pool of the static blocks as candidate blocks (which may also be referred to as spare blocks) for replacing other static blocks, and may designate a pool of the dynamic blocks as candidate blocks for replacing other dynamic blocks. But designating separate pools of blocks as candidate blocks may reduce the functional storage capacity of the memory system and be more restrictive.

According to the techniques described herein, the functional storage capacity of a memory system may be increased by designating dynamic blocks as universal spare blocks for replacing multiple types of blocks, including dynamic blocks and static blocks. For example, if a static block satisfies a replacement condition (e.g., has been identified as being ready to be replaced to prevent various challenges or issues), the memory system may use a dynamic block from the universal spare blocks to replace the static block. To track the replacement of the static block with the dynamic block, the memory system may update replacement information to indicate that the dynamic block is to be used instead of (e.g., in place of, in lieu of) the static block for subsequent access operations. Thus, the memory system may use dynamic blocks as universal spare blocks for type-agnostic block replacement, which may reduce the quantity of blocks (e.g., static blocks) used as spare blocks, thus increasing the functional storage capacity of a memory system, among other advantages.

In addition to applicability in memory systems as described herein, techniques for universal spare blocks may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by increasing the functional memory capacity of the electronic devices, which may improve user experience, among other benefits.

In addition to applicability in memory systems as described herein, techniques for universal spare blocks may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by allowing for reduced materials used in production of electronic devices without sacrificing functional memory capacity (e.g., because static blocks can be used for storing information rather than used as spare blocks), which may reduce electronic waste, among other benefits.

Features of the disclosure are illustrated and described in the context of systems, devices, and circuits. Features of the disclosure are further illustrated and described in the context of memory dies, a process flow, and a flowchart.

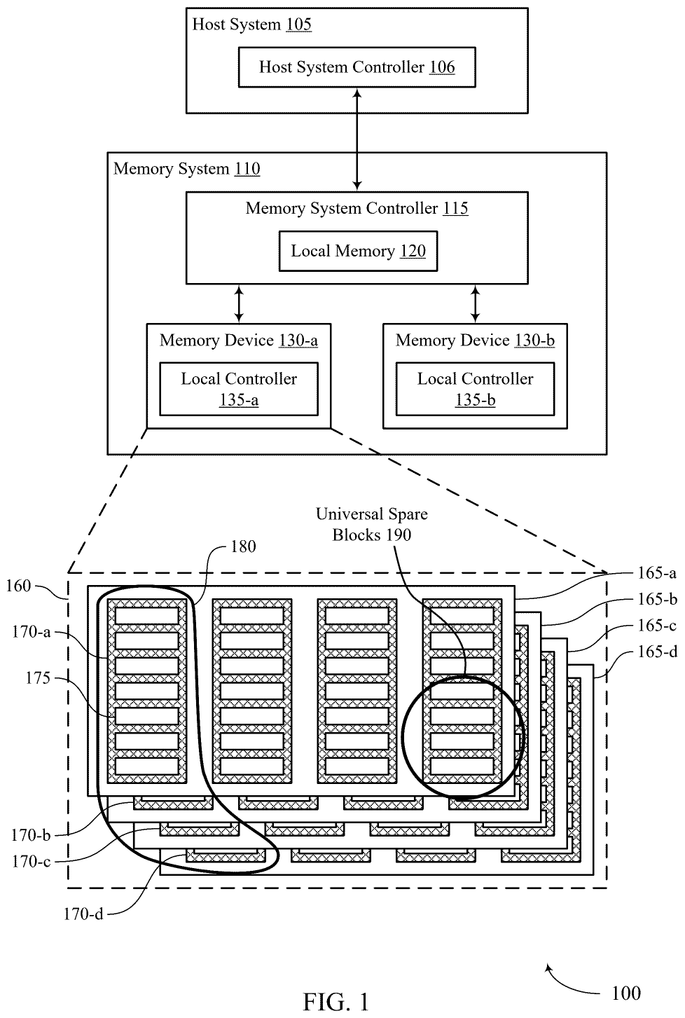

FIG. 1 shows an example of a system 100 that supports use of dynamic blocks for repairs in a memory system in accordance with examples as disclosed herein. The system 100 includes a host system 105 coupled with a memory system 110. The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

The system 100 may include any quantity of non-transitory computer readable media that support use of dynamic blocks for repairs in a memory system. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some examples, the memory system 110 may configure a first set of blocks 170 as static blocks and may configure a second set of blocks 170 as dynamic blocks. The static blocks may support a single type of write operation (e.g., an SLC write operation) whereas the dynamic blocks may support multiple (e.g., different) types of write operations (e.g., an SLC write operation, a multi-bit write operation). Examples of multi-bit write operations include a bi-level-cell (BLC) write operation that writes two bits per memory cell, a triple-level-cell (TLC) write operation that writes three bits per memory cell, and a quad-level-cell (QLC) write operation that writes four bits per memory cell.

In some examples, the memory system 110 may support different sub-types of SLC write operations, such as a first SLC write operation that uses a lower write voltage and/or shorter writing time, and may have a smaller read window, and a second SLC write operation that uses a higher write voltage and/or longer writing time, and may have a larger read window. In such scenarios, the first SLC write operation may be used to write dynamic blocks and the second SLC write operation may be used to write static blocks.

Different types of write operations may be associated with different endurance metrics and different reliability metrics. For example, SLC write operations may be associated with a higher endurance metric than multi-bit write operations, where an endurance metric refer to a threshold quantity of write operations and erase operations (also referred to as program and erase cycles (PECs)) a memory cell can withstand before the memory cell fails. SLC write operations may also be associated with a higher reliability metric than multi-bit operations, where a reliability metric refers to a quantity of time a memory cell is able to store information without corruption.

The memory system 110 may support repair procedures in which one block (e.g., a block that satisfies a replacement condition) is replaced with a spare block. For instance, the memory system 110 may monitor the functionality of a block 170 and, if the block 170 satisfies a replacement condition, may replace the block 170 with a spare block. A spare block may refer to a block that is reserved or designated as a candidate block for replacing other blocks. Replacing a first block with a second block may involve the memory system 110 updating replacement information to indicate that the second block is to be used instead of the first block for subsequent access operations. In some examples, replacing a first block with a second block may involve copying information from the first block to the second block.

Although potentially used for maintenance operations such a wear-leveling and garbage collection, a spare block may not contribute to the functional storage capacity of the memory system 110, which may refer to the total amount of information the memory system 110 is capable of storing at a given time. So, higher quantities of spare blocks may decrease the efficiency and functional storage capacity of the memory system 110.

According to the techniques described herein, the memory system 110 may reduce the quantity of spare blocks (relative to techniques that have separate pools of spare blocks per type of block) by using the spare dynamic blocks as universal spare blocks 190 to replace any type of block (e.g., static blocks, dynamic blocks). Use of the dynamic block as universal spare blocks 190 (e.g., spare blocks that can be used to replace multiple types of blocks or any type of block) may allow the memory system 110 to re-purpose static blocks (that would otherwise be designated as spare blocks) as normal blocks (e.g., blocks that are not reserved for replacing other blocks), thereby increasing the functional storage capacity of the memory system 110. Use of dynamic blocks as the universal spare blocks 190 may be managed by one or more controllers such as the local controllers 135, the memory system controller 115, or both.

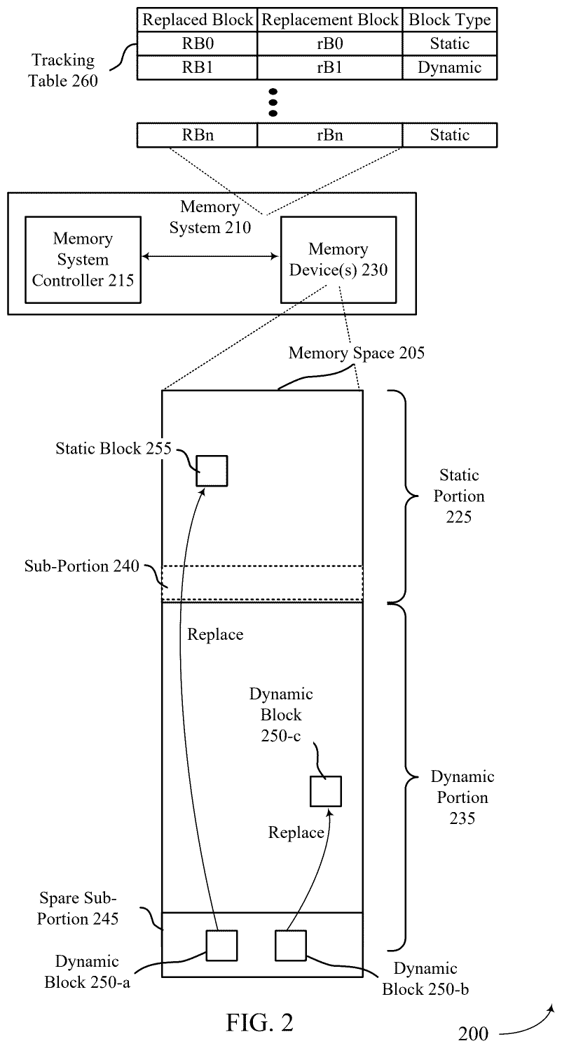

FIG. 2 shows an example of a memory system 200 that supports use of dynamic blocks for repairs in accordance with examples as disclosed herein. The memory system 200 may be an example of the memory system 110 as described with reference to FIG. 1. The memory system 210 may include a memory system controller 215, which may be an example of the memory system controller 115. The memory system 210 may also include one or more memory device(s) 230, which may be examples of the memory devices 130, and thus may include or be coupled with local controllers similar to the local controllers 135. According to the techniques described here, the memory system 210 may increase the functional storage capacity of the memory system 210 by using a subset of dynamic blocks as universal spare blocks.

The operations of memory system 210 may be implemented by the memory system controller 215 and the memory device(s) 230. The operations of the memory system controller 215 may be implemented in instructions stored on a local memory (e.g., local memory 120) of the memory system controller 215 and executed by a processor of the memory system controller 215. The operations of a memory device 230 may be implemented in instructions stored on a local memory, received from the memory system controller 215, or both, and executed by a local controller (e.g., a local controller 135).

The memory space 205 may represent the collective memory, or part of the collective memory, of the memory device(s) 230. The memory space 205 may include a static portion 225 that includes a set of static blocks and may include a dynamic portion 235 that includes a set of dynamic blocks. The memory system 210 may configure (select blocks for inclusion in) the static portion 225 and the dynamic portion 235 autonomously or with assistance from a host system. In some examples, the static blocks may be used to store both user data as well as system information (e.g., a flash translation layer (FTL) for performing address translation, L2P information for address translation) that the memory system 210 uses to operate, whereas the dynamic blocks may be used to store user data.

A single type of write operation (e.g., an SLC write operation) may be permitted for writing the static blocks in the static portion 225, whereas multiple types of write operations (e.g., an SLC write operation, a multi-bit write operation) may be permitted for writing the dynamic blocks in the dynamic portion 235. Put another way, a static block of the static portion 225 may be written using (potentially exclusively) the same type of write operation (e.g., an SLC write operation) whereas a dynamic block in the dynamic portion 235 may be written using different types of write operations (e.g., an SLC write operation, a TLC write operation). In some examples, the SLC write operation permitted for the dynamic portion 235 may be the first sub-type of SLC write operation and the SLC write operation permitted for the static portion 225 may be the second sub-type of SLC write operation.

Rather than having separate, type-specific spare blocks for each type of block, which may be an inefficient use of memory resources, the memory system 210 may use dynamic blocks as universal spare blocks that are permitted to replace multiple types of blocks. For example, rather than using the static blocks in sub-portion 240 as spare blocks for the remainder of the static blocks in the static portion 225, the memory system 210 may use the dynamic blocks in sub-portion 245 as universal spare blocks for both the static portion 225 and the dynamic portion 235. Accordingly, the memory system 210 may re-purpose the static blocks in sub-portion 240 as normal blocks, which may increase the functional capacity of the memory system 210.

As an example, the memory system 210 may use dynamic block 250-a, from the spare sub-portion 245, to replace static block 255, and may use dynamic block 250-b, from the spare sub-portion 245, to replace dynamic block 250-c. Thus, dynamic blocks 250 from the spare sub-portion 245 may be used to replace blocks in the static portion 225 and the dynamic portion 235.

Replacing a block with spare block may involve copying information from the block to the spare block, updating replacement information (e.g., in the tracking table 260) to indicate that the spare block is to be used instead of the block for subsequent access operations, or both. The tracking table 260 may indicate pairs of blocks, one of which has been replaced by the other. For example, the tracking table 260 may indicate that block RB0has been replaced by block rB0, may indicate that block RBI has been replaced by block rB1, etc. In some examples, the tracking table 260 may indicate blocks using the physical addresses of the blocks. The tracking table 260 may be stored in the memory device(s) 230 or in a local memory coupled with or included in the memory system controller 215.

In some examples, the memory system 210 may maintain a second tracking table for tracking the spare blocks that have been used as replacement blocks (and thus are no longer candidate blocks for replacing other blocks). For example, the memory system 210 may update spare information (e.g., in the second tracking table) to indicate that a spare block has been used as a replacement block.

In some examples, the tracking table 260 may also indicate the type of the replaced block so that the memory system 210 is able to use the replacement block as that type of block. For example, if block RB0 is a static block and block rB0 is a dynamic block, the tracking table 260 may indicate that block rB0 is to be used as a static block. Accordingly, for subsequent write operations to block rB0 (e.g., write operations initiated after updating the replacement information in the tracking table 260), the memory system 210 may use the type of write operation permitted for static blocks (and may refrain from using other types of write operations), even though other types of write operations may have already been performed on block rB0 (e.g., before replacing block RB0). Thus, in some examples, a universal spare block may be written with the first sub-type of SLC write operation before replacement (e.g., as part of maintenance operations such as wear-leveling) and may be written with the second sub-type of SLC write operation after replacement.

The memory system 210 may determine to replace a block if the block satisfies a condition for replacement, referred to as a replacement condition. In one example, the memory system 210 may determine to replace a block if the block experiences a write fail (also referred to as a program fail). For instance, the memory system 210 may determine to replace a block if a write status fail (WSF) flag (also referred to as a program status fail (PSF) flag) is received at the memory system controller 215 from the memory device 230. In another example, the memory system 210 may determine to replace a block if the block experiences an erase fail. For instance, the memory system 210 may determine to replace a block if an erase status fail (ESF) flag is received at the memory system controller 215 from the memory device 230. In another example, the memory system 210 may determine to replace a block if the block experiences a threshold quantity of uncorrectable errors (e.g., one uncorrectable error) or a threshold quantity of correctable errors. For instance, the memory system 210 may determine to replace a block if an uncorrectable error flag is received at the memory system controller 215 from the memory device 230.

Based on (e.g., in response to) determining to replace a block, the memory system 210 may select another block (referred to as the replacement block) for replacing the block. The memory system 210 may select the replacement block from the universal spare blocks in the spare sub-portion 245. In some examples, the memory system 210 may select the replacement block based on one or more additional criteria. For example, the memory system 210 may select the replacement block based on the collective quantity of write operations and erase operations performed on the replacement block, which may also be referred to as the program and erase cycles (PECs) of the block. For instance, the memory system 210 may select the replacement block based on (e.g., due to) the replacement block having the lowest quantity of write operations and erase operations relative to other blocks in the spare sub-portion 245. To do so, the memory system 210 may compare the quantity of write operations and erase operations performed on the replacement block with the respective quantities of write operations and erase operations performed on the other blocks in the spare sub-portion 245. The memory system 210 may (e.g., based on referencing the second table) exclude from the comparison any spare blocks that have already been used as replacement blocks.

In some examples, may select the replacement block based on (e.g., because of) a physical location of the replacement block on the memory die that includes the replacement block. For example, the memory system 210 may select the replacement block based on (e.g., because) the replacement block being a threshold distance from the center of the memory die, being a threshold distance from the edge of the memory die, or both. In some examples, may select the replacement block based on (e.g., due to) the replacement block being in the same plane as the replaced block.

Thus, the memory system 210 may use a subset of dynamic blocks as universal spare blocks for replacing other blocks in the memory space 205.

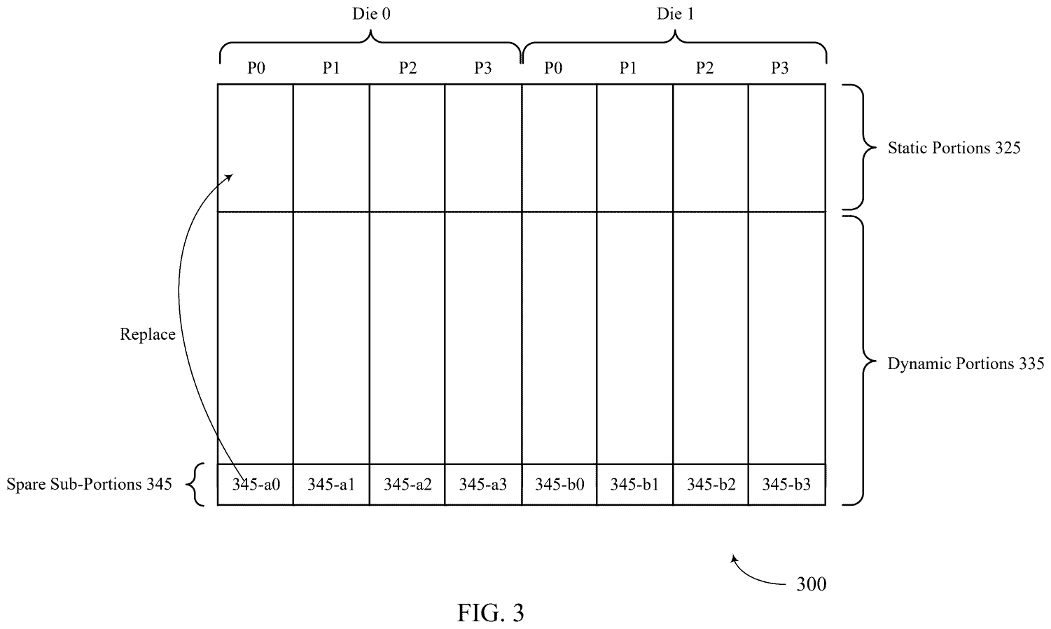

FIG. 3 shows an example of memory dies 300 that support use of dynamic blocks for repairs in a memory system in accordance with examples as disclosed herein. The memory dies 300 may be examples of memory dies included in the memory device(s) 230 as described with reference to FIG. 2. The memory dies 300 may include die 0 and die 1; however, other quantities of memory dies are contemplated and within the scope of the present disclosure.

A die may have one or more respective planes, denoted plane P0, plane P1, plane P2, and plane P3. A plane may have at least a static portion 325 that includes static blocks and a dynamic portion 335 that includes dynamic blocks. A subset of dynamic blocks in the dynamic portion 335 of a plane may form the spare sub-portion 345 for that plane. In some examples (e.g., if the blocks in the spare sub-portion 345 are involved in maintenance operations like wear-leveling), the blocks included in the spare sub-portion 345 may change over time. In other examples, the blocks included in the spare sub-portion 345 may be fixed. In any case, the memory system may use the second tracking table to indicate the blocks (e.g., by their respective physical addresses) included in the spare sub-portion 345. Upon use of a spare block as a replacement block, the memory system may update the second tracking table to reflect that the spare block has been used as a replacement block (and thus is no longer a candidate for replacement).

A memory system that includes die 0 and die 1 may use blocks from the spare sub-portion 345 to replace other blocks of the dies (e.g., as part of a repair procedure). For example, the memory system may use a dynamic block from spare sub-portion 345-a0 to replace a static block in the static portion 325 of plane 0 of die 0. The memory system may select the dynamic block based on (e.g., due to) the dynamic block being included in the spare sub-portion 345, which the memory system may determine by referencing the second tracking table. In some examples, the memory system may condition selection of the dynamic block on the dynamic block being in the same plane as the static block being replaced.

Thus, a memory system may use dynamic blocks in a spare sub-portion 345 of a plane to replace other blocks in the corresponding static portion 325 of the same plane.

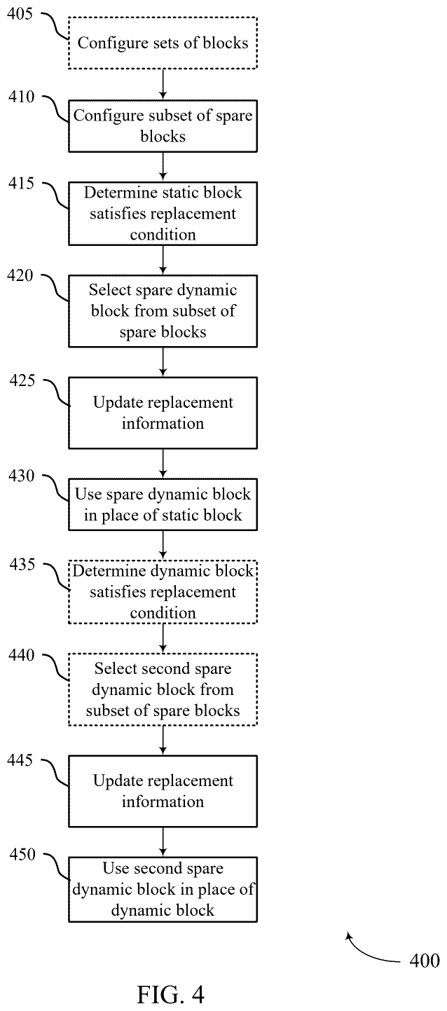

FIG. 4 shows an example of a process flow 400 that supports use of dynamic blocks for repairs in a memory system in accordance with examples as disclosed herein. The process flow 400 may be implemented by a memory system such as a memory system 110 or a memory system 210 as described with reference to FIG. 1 and FIG. 2, respectively. The memory system may include a plurality of blocks.

Aspects of the process flow 400 may be implemented by a controller, such as a memory system controller 115, a local controller 135, or a memory system controller 215, among other components. Additionally or alternatively, aspects of the process flow 400 may be implemented as instructions stored in memory (e.g., firmware stored in a memory coupled with the memory system controller 215). For example, the instructions, when executed by a controller (e.g., the memory system controller 215), may cause the controller to perform the operations of the process flow 400.

At 405, a first set of the plurality of blocks may be configured as a set of static blocks and a second set of the plurality of blocks may be configured as a set of dynamic blocks. A single type of write operation may be permitted for the static blocks whereas multiple types of write operations may be permitted for the dynamic blocks. Configuring the set of static blocks may involve storing an indication of the blocks included in the set of static blocks. Configuring the set of dynamic blocks may involve storing an indication of the blocks included in the set of dynamic blocks.

At 410, a subset of the dynamic blocks may be configured as spare blocks. Configuring the subset of dynamic blocks may involve storing an indication that the subset of dynamic blocks are reserved as spare blocks (e.g., candidate blocks for replacing other blocks). In some examples, the second tracking table indicate the subset of dynamic blocks that are configured as spare blocks.

At 415, it may be determined that a static block satisfies a replacement condition. For example, the memory system may determine, based on (e.g., in response to) a write status fail flag for the static block, that the static block has experienced a write operation failure. In some examples, the write status fail flag may be transmitted from the memory device 230 to the memory system controller 215. The memory device 230 may transmit the write status fail flag based on (e.g., in response to) performing a write status check procedure in which the memory device 230 writes to the static block and then compares the threshold voltages of the memory cells in the block with reference threshold voltages (e.g., reference threshold voltages that are associated with the single type of write operation permitted for static blocks).

In another example, the memory system may determine, based on (e.g., in response to) an erase status fail flag for the static block, that the static block has experienced an erase operation failure. In some examples, the erase status fail flag may be transmitted from the memory device 230 to the memory system controller 215. The memory device 230 may transmit the erase status fail flag based on (e.g., in response to) performing an erase status check procedure in which the memory device 230 erases the static block and then compares the threshold voltages of the memory cells in the block with reference threshold voltages.

In another examples, the memory system may determine, based on (e.g., in response to) an uncorrectable error flag, that the static block has experienced an uncorrectable error. In some examples, the uncorrectable error flag may be transmitted from the memory device 230 to the memory system controller 215. The memory device 230 may transmit the uncorrectable error flag based on performing an error correction code (ECC) procedure that detects one or more errors.

At 420, a spare dynamic block from the subset of spare blocks may be selected to replace the static block. In some examples, the spare dynamic block may be selected based on (e.g., due to) the spare dynamic block being included in the subset of spare blocks, based on (e.g., due to) the spare dynamic block being in the same die and the same plane as the static block, or both. In some examples, the spare dynamic block may be selected based on (e.g., due to) the second tracking table indicating that the spare dynamic block has not yet been used a replacement block.

In some examples, the spare dynamic block may be selected based on the collective (e.g., cumulative) quantity of write operations and erase operations performed on the spare dynamic block. For example, the spare dynamic block may be selected based on (e.g., due to) the quantity of write operations and erase operations performed on the spare dynamic block being less than corresponding quantities of write operations and erase operations performs on the other spare dynamic blocks. For example, the memory system may compare the quantity of write operations and erase operations with a second quantity of write operations and erase operations associated with a second spare dynamic block and may select the dynamic spare block based on (e.g., due to) the quantity being less than the second quantity.

In some examples, the spare dynamic block may be selected based on the physical location of the spare dynamic block on the memory die that includes the spare dynamic block (e.g., because blocks at the center of the memory die or at the edges of the memory die may be more susceptible to deleterious effects). For example, the spare dynamic block may be selected based on (e.g., due to) the spare dynamic block being positioned a threshold distance from the center of the memory die, based on the spare dynamic block being positioned a threshold distance from the nearest edge of the memory die, or both.

At 425, replacement information may be updated to indicate that the spare dynamic block has replaced the static block (and thus that the spare dynamic is to be used instead of the static block for subsequent access operations). In some examples, the replacement information may also be updated to indicate that the spare dynamic block is to be used as a static-type block. In some examples, the second tracking table may be updated to indicate that the spare dynamic block has been used in a replacement. In some examples, information written to the static block may be copied from the static block to the spare dynamic block (e.g., to preserve the information for subsequent access).

At 430 (e.g., after updating the replacement information), the spare dynamic block may be used in place of the static block for subsequent access operations. For example, an access operation (e.g., a read operation, a write operation) that implicates the static block may be performed on the spare dynamic block instead of being performed on the static block. As an illustration, if a write operation for data implicates the static block (e.g., by targeting a subset of blocks that includes the static block), the memory system may write the data to the spare dynamic block instead of writing the data to the static block. Similarly, if a read operation for data implicates the static block (e.g., by targeting a subset of blocks that includes the static block), the memory system may read the data from the spare dynamic block instead of reading the data from the static block. Further, the memory system may use the spare dynamic block as a static-type block in that the memory system may perform a single type of write operation (e.g., an SLC operation) on the spare dynamic block. In some examples, the SLC operation may be a different sub-type than an SLC operation previously performed on the spare dynamic block (e.g., as part of a maintenance operation).

In some examples, the memory system may also replace a dynamic block. For example, at 435, it may be determined that a dynamic block satisfies a replacement condition. For instance, the memory system may determine, based on (e.g., in response to) a write status fail flag for the dynamic block, that the dynamic block has experienced a write operation failure. In some examples, the write status fail flag may be transmitted from the memory device 230 to the memory system controller 215. The memory device 230 may transmit the write status fail flag based on (e.g., in response to) performing a write status check procedure in which the memory device 230 writes to the dynamic block and then compares the threshold voltages of the memory cells in the dynamic block with reference threshold voltages (e.g., reference threshold voltages that are associated with the type of write operation used for dynamic blocks).

In another example, the memory system may determine, based on (e.g., in response to) an erase status fail flag for the dynamic block, that the dynamic block has experienced an erase operation failure. In some examples, the erase status fail flag may be transmitted from the memory device 230 to the memory system controller 215. The memory device 230 may transmit the erase status fail flag based on (e.g., in response to) performing an erase status check procedure in which the memory device 230 erases the dynamic block and then compares the threshold voltages of the memory cells in the dynamic block with reference threshold voltages.

In another examples, the memory system may determine, based on (e.g., in response to) an uncorrectable error flag, that the dynamic block has experienced an uncorrectable error. In some examples, the uncorrectable error flag may be transmitted from the memory device 230 to the memory system controller 215. The memory device 230 may transmit the uncorrectable error flag based on (e.g., in response to) performing an ECC procedure that detects one or more errors.

At 440, a second spare dynamic block from the subset of spare blocks may be selected to replace the dynamic block. In some examples, the second spare dynamic block may be selected based on (e.g., due to) the second spare dynamic block being included in the subset of spare blocks, based on (e.g., due to) the second spare dynamic block being in the same die and the same plane as the static block, or both. In some examples, the second spare dynamic block may be selected based on the collective (e.g., cumulative) quantity of write operations and erase operations performed on the second spare dynamic block. In some examples, the second spare dynamic block may be selected based on (e.g., due to) the physical location of the spare dynamic block on the memory die that includes the spare dynamic block.

At 445, replacement information may be updated to indicate that the second spare dynamic block has replaced the dynamic block (and thus that the second spare dynamic is to be used instead of the dynamic block for subsequent access operations). In some examples, the replacement information may also be updated to indicate that the second spare dynamic block is to be used as a static-type block. In some examples, the second tracking table may be updated to indicate that the spare dynamic block has been used in a replacement. In some examples, information written to the dynamic block may be copied from the dynamic block to the second spare dynamic block (e.g., to preserve the information for subsequent access).

At 450 (e.g., after updating the replacement information), the second spare dynamic block may be used in place of the dynamic block for subsequent access operations. For example, an access operation (e.g., a read operation, a write operation) that implicates the dynamic block may be performed on the second spare dynamic block instead of being performed on the dynamic block. As an illustration, if a write operation for data implicates the dynamic block (e.g., by targeting a subset of blocks that includes the dynamic block), the memory system may write the data to the second spare dynamic block instead of writing the data to the dynamic block. Similarly, if a read operation for data implicates the dynamic block (e.g., by targeting a subset of blocks that includes the dynamic block), the memory system may read the data from the second spare dynamic block instead of reading the data from the dynamic block. Further, the memory system may use the second spare dynamic block as a static-type block in that the memory system may perform a single type of write operation (e.g., an SLC operation) on the second spare dynamic block.

Thus, spare dynamic blocks may be used to replace different types of blocks, including static blocks and dynamic blocks.

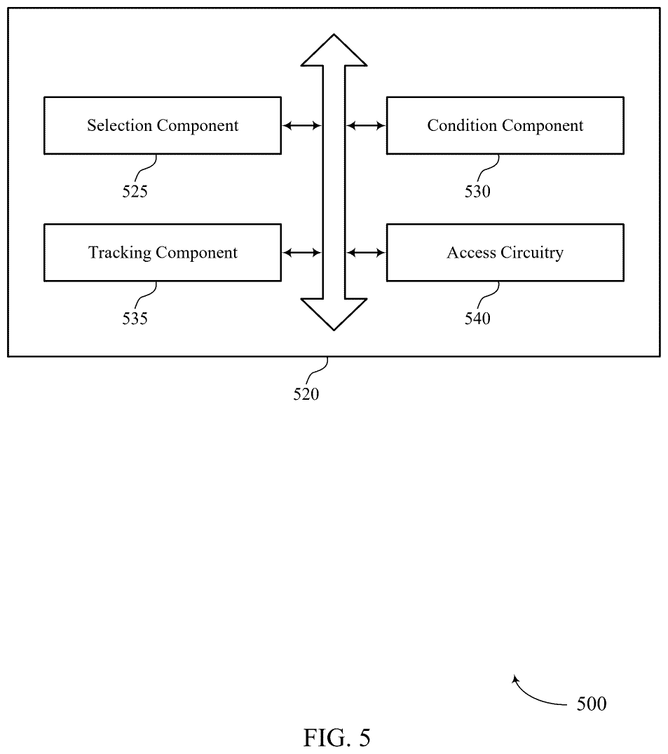

FIG. 5 shows a block diagram 500 of a memory system 520 that supports use of dynamic blocks for repairs in a memory system in accordance with examples as disclosed herein. The memory system 520 may be an example of aspects of a memory system as described with reference to FIGS. 1 through 4. The memory system 520, or various components thereof, may be an example of means for performing various aspects of use of dynamic blocks for repairs in a memory system as described herein. For example, the memory system 520 may include a selection component 525, a condition component 530, a tracking component 535, an access circuitry 540, or any combination thereof. Each of these components, or components of subcomponents thereof (e.g., one or more processors, one or more memories), may communicate, directly or indirectly, with one another (e.g., via one or more buses).

The selection component 525 may be configured as or otherwise support a means for selecting, from a set of dynamic blocks, a subset of dynamic blocks as candidates for replacing other blocks, the set of dynamic blocks including blocks to which multiple types of write operations are permitted, each of the multiple types of write operations associated with different quantities of stored bits per memory cell. The condition component 530 may be configured as or otherwise support a means for determining whether a static block in a set of static blocks has satisfied a condition for replacement, the set of static blocks including blocks to which a single type of write operation is permitted. The tracking component 535 may be configured as or otherwise support a means for updating, based at least in part on determining that the static block satisfies the condition for replacement, replacement information for tracking block replacements to indicate that a dynamic block in the subset of dynamic blocks is to be used instead of the static block for subsequent access operations.

In some examples, to support determining that the static block has satisfied the condition for replacement, the condition component 530 may be configured as or otherwise support a means for determining that a write fail status flag for the static block has been received, where the write fail status flag indicates that a write operation performed on the static block has failed.

In some examples, to support determining that the static block has satisfied the condition for replacement, the condition component 530 may be configured as or otherwise support a means for determining that an erase fail status flag for the static block has been received, where the erase fail status flag indicates that an erase operation performed on the static block has failed.

In some examples, to support determining that the static block has satisfied the condition for replacement, the condition component 530 may be configured as or otherwise support a means for determining that the static block has a threshold quantity of uncorrectable errors.

In some examples, the selection component 525 may be configured as or otherwise support a means for selecting the dynamic block for use instead of the static block based at least in part on the dynamic block being included in the subset of dynamic blocks and based at least in part on a quantity of write operations and erase operations performed on the dynamic block.

In some examples, the selection component 525 may be configured as or otherwise support a means for comparing the quantity of write operations and erase operations with a second quantity of write operations and erase operations associated with a second dynamic block from the subset of dynamic blocks, where the dynamic block is selected based at least in part on the quantity being less than the second quantity.

In some examples, the selection component 525 may be configured as or otherwise support a means for selecting the dynamic block for use instead of the static block based at least in part on a physical location of the dynamic block on a memory die that includes the set of dynamic blocks.

In some examples, the selection component 525 may be configured as or otherwise support a means for selecting the dynamic block for use instead of the static block based at least in part on the dynamic block being included in the subset of dynamic blocks and based at least in part on the dynamic block being in a same plane as the static block.

In some examples, the access circuitry 540 may be configured as or otherwise support a means for refraining, based at least in part on updating the replacement information, from performing types of write operations on the dynamic block other than the single type of write operation.

In some examples, the single type of write operation includes an SLC write operation that writes a single bit per memory cell. In some examples, the multiple types of write operations include the SLC write operation and a multi-bit write operation that writes multiple bits per memory cell.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

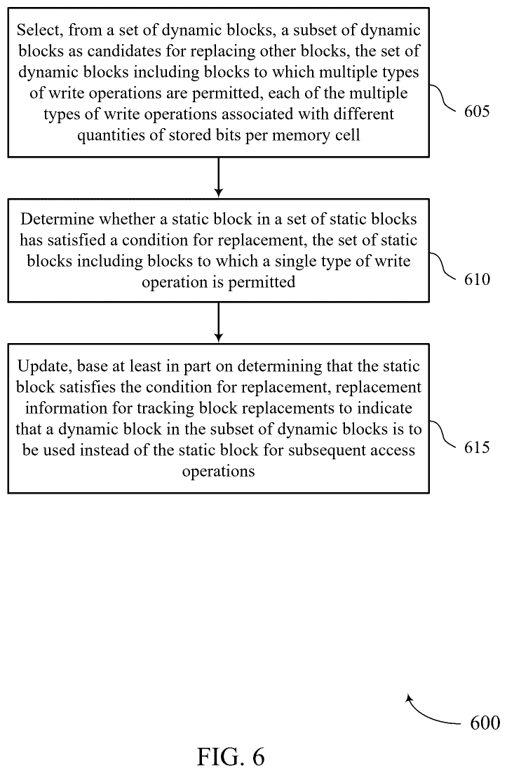

FIG. 6 shows a flowchart illustrating a method 600 that supports use of dynamic blocks for repairs in a memory system in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include selecting, from a set of dynamic blocks, a subset of dynamic blocks as candidates for replacing other blocks, the set of dynamic blocks including blocks to which multiple types of write operations are permitted, each of the multiple types of write operations associated with different quantities of stored bits per memory cell. In some examples, aspects of the operations of 605 may be performed by a selection component 525 as described with reference to FIG. 5.

At 610, the method may include determining whether a static block in a set of static blocks has satisfied a condition for replacement, the set of static blocks including blocks to which a single type of write operation is permitted. In some examples, aspects of the operations of 610 may be performed by a condition component 530 as described with reference to FIG. 5.

At 615, the method may include updating, based at least in part on determining that the static block satisfies the condition for replacement, replacement information for tracking block replacements to indicate that a dynamic block in the subset of dynamic blocks is to be used instead of the static block for subsequent access operations. In some examples, aspects of the operations of 615 may be performed by a tracking component 535 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for selecting, from a set of dynamic blocks, a subset of dynamic blocks as candidates for replacing other blocks, the set of dynamic blocks including blocks to which multiple types of write operations are permitted, each of the multiple types of write operations associated with different quantities of stored bits per memory cell; determining whether a static block in a set of static blocks has satisfied a condition for replacement, the set of static blocks including blocks to which a single type of write operation is permitted; and updating, based at least in part on determining that the static block satisfies the condition for replacement, replacement information for tracking block replacements to indicate that a dynamic block in the subset of dynamic blocks is to be used instead of the static block for subsequent access operations.

Aspect 2: The method, apparatus, or non-transitory computer-readable medium of aspect 1, where determining that the static block has satisfied the condition for replacement includes operations, features, circuitry, logic, means, or instructions, or any combination thereof for determining that a write fail status flag for the static block has been received, where the write fail status flag indicates that a write operation performed on the static block has failed.

Aspect 3: The method, apparatus, or non-transitory computer-readable medium of any of aspects 1 through 2, where determining that the static block has satisfied the condition for replacement includes operations, features, circuitry, logic, means, or instructions, or any combination thereof for determining that an erase fail status flag for the static block has been received, where the erase fail status flag indicates that an erase operation performed on the static block has failed.

Aspect 4: The method, apparatus, or non-transitory computer-readable medium of any of aspects 1 through 3, where determining that the static block has satisfied the condition for replacement includes operations, features, circuitry, logic, means, or instructions, or any combination thereof for determining that the static block has a threshold quantity of uncorrectable errors.

Aspect 5: The method, apparatus, or non-transitory computer-readable medium of any of aspects 1 through 4, further including operations, features, circuitry, logic, means, or instructions, or any combination thereof for selecting the dynamic block for use instead of the static block based at least in part on the dynamic block being included in the subset of dynamic blocks and based at least in part on a quantity of write operations and erase operations performed on the dynamic block.

Aspect 6: The method, apparatus, or non-transitory computer-readable medium of aspect 5, further including operations, features, circuitry, logic, means, or instructions, or any combination thereof for comparing the quantity of write operations and erase operations with a second quantity of write operations and erase operations associated with a second dynamic block from the subset of dynamic blocks, where the dynamic block is selected based at least in part on the quantity being less than the second quantity.

Aspect 7: The method, apparatus, or non-transitory computer-readable medium of any of aspects 1 through 6, further including operations, features, circuitry, logic, means, or instructions, or any combination thereof for selecting the dynamic block for use instead of the static block based at least in part on a physical location of the dynamic block on a memory die that includes the set of dynamic blocks.

Aspect 8: The method, apparatus, or non-transitory computer-readable medium of any of aspects 1 through 7, further including operations, features, circuitry, logic, means, or instructions, or any combination thereof for selecting the dynamic block for use instead of the static block based at least in part on the dynamic block being included in the subset of dynamic blocks and based at least in part on the dynamic block being in a same plane as the static block.

Aspect 9: The method, apparatus, or non-transitory computer-readable medium of any of aspects 1 through 8, further including operations, features, circuitry, logic, means, or instructions, or any combination thereof for refraining, based at least in part on updating the replacement information, from performing types of write operations on the dynamic block other than the single type of write operation.

Aspect 10: The method, apparatus, or non-transitory computer-readable medium of any of aspects 1 through 9, where the single type of write operation includes a single-level-cell (SLC) write operation that writes a single bit per memory cell.

Aspect 11: The method, apparatus, or non-transitory computer-readable medium of aspect 10, where the multiple types of write operations include the SLC write operation and a multi-bit write operation that writes multiple bits per memory cell.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

As used herein, the term “substantially” means that the modified characteristic (e.g., a verb or adjective modified by the term substantially) need not be absolute but is close enough to achieve the advantages of the characteristic.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a memory device; and
one or more controllers coupled with the memory device and configured to cause the apparatus to:
select, from a set of dynamic blocks, a subset of dynamic blocks as candidates for replacing other blocks, the set of dynamic blocks comprising blocks to which multiple types of write operations are permitted, each of the multiple types of write operations associated with different quantities of stored bits per memory cell;
determine whether a static block in a set of static blocks has satisfied a condition for replacement, the set of static blocks comprising blocks to which a single type of write operation is permitted; and
update, based at least in part on determining that the static block satisfies the condition for replacement, replacement information for tracking block replacements to indicate that a dynamic block in the subset of dynamic blocks is to be used instead of the static block for subsequent access operations.

2. The apparatus of claim 1, wherein the one or more controllers are configured to cause the apparatus to determine that the static block has satisfied the condition for replacement by being configured to cause the apparatus to:
determine that a write fail status flag for the static block has been received, wherein the write fail status flag indicates that a write operation performed on the static block has failed.

3. The apparatus of claim 1, wherein the one or more controllers are configured to cause the apparatus to determine that the static block has satisfied the condition for replacement by being configured to cause the apparatus to:
determine that an erase fail status flag for the static block has been received, wherein the erase fail status flag indicates that an erase operation performed on the static block has failed.

4. The apparatus of claim 1, wherein the one or more controllers are configured to cause the apparatus to determine that the static block has satisfied the condition for replacement by being configured to cause the apparatus to:
determine that the static block has a threshold quantity of uncorrectable errors.

5. The apparatus of claim 1, wherein the one or more controllers are further configured to cause the apparatus to:
select the dynamic block for use instead of the static block based at least in part on the dynamic block being included in the subset of dynamic blocks and based at least in part on a quantity of write operations and erase operations performed on the dynamic block.

6. The apparatus of claim 5, wherein the one or more controllers are further configured to cause the apparatus to:
compare the quantity of write operations and erase operations with a second quantity of write operations and erase operations associated with a second dynamic block from the subset of dynamic blocks, wherein the dynamic block is selected based at least in part on the quantity being less than the second quantity.

7. The apparatus of claim 1, wherein the one or more controllers are further configured to cause the apparatus to:
select the dynamic block for use instead of the static block based at least in part on a physical location of the dynamic block on a memory die that includes the set of dynamic blocks.

8. The apparatus of claim 1, wherein the one or more controllers are further configured to cause the apparatus to:
select the dynamic block for use instead of the static block based at least in part on the dynamic block being included in the subset of dynamic blocks and based at least in part on the dynamic block being in a same plane as the static block.

9. The apparatus of claim 1, wherein the one or more controllers are further configured to cause the apparatus to:
refrain, based at least in part on updating the replacement information, from performing types of write operations on the dynamic block other than the single type of write operation.

10. The apparatus of claim 1, wherein the single type of write operation comprises a single-level-cell (SLC) write operation that writes a single bit per memory cell.

11. The apparatus of claim 10, wherein the multiple types of write operations comprise the SLC write operation and a multi-bit write operation that writes multiple bits per memory cell.

12. A method, comprising:
selecting, from a set of dynamic blocks, a subset of dynamic blocks as candidates for replacing other blocks, the set of dynamic blocks comprising blocks to which multiple types of write operations are permitted, each of the multiple types of write operations associated with different quantities of stored bits per memory cell;
determining whether a static block in a set of static blocks has satisfied a condition for replacement, the set of static blocks comprising blocks to which a single type of write operation is permitted; and
updating, based at least in part on determining that the static block satisfies the condition for replacement, replacement information for tracking block replacements to indicate that a dynamic block in the subset of dynamic blocks is to be used instead of the static block for subsequent access operations.

13. The method of claim 12, wherein determining that the static block has satisfied the condition for replacement comprises:
determining that a write fail status flag for the static block has been received, wherein the write fail status flag indicates that a write operation performed on the static block has failed.

14. The method of claim 12, wherein determining that the static block has satisfied the condition for replacement comprises:
determining that an erase fail status flag for the static block has been received, wherein the erase fail status flag indicates that an erase operation performed on the static block has failed.

15. The method of claim 12, wherein determining that the static block has satisfied the condition for replacement comprises:
determining that the static block has a threshold quantity of uncorrectable errors.

16. The method of claim 12, further comprising:
selecting the dynamic block for use instead of the static block based at least in part on the dynamic block being included in the subset of dynamic blocks and based at least in part on a quantity of write operations and erase operations performed on the dynamic block.

17. The method of claim 16, further comprising:
comparing the quantity of write operations and erase operations with a second quantity of write operations and erase operations associated with a second dynamic block from the subset of dynamic blocks, wherein the dynamic block is selected based at least in part on the quantity being less than the second quantity.

18. The method of claim 12, further comprising:
selecting the dynamic block for use instead of the static block based at least in part on a physical location of the dynamic block on a memory die that includes the set of dynamic blocks.

19. The method of claim 12, further comprising:
selecting the dynamic block for use instead of the static block based at least in part on the dynamic block being included in the subset of dynamic blocks and based at least in part on the dynamic block being in a same plane as the static block.

20. The method of claim 12, further comprising:
refraining, based at least in part on updating the replacement information, from performing types of write operations on the dynamic block other than the single type of write operation.

21. The method of claim 12, wherein the single type of write operation comprises a single-level-cell (SLC) write operation that writes a single bit per memory cell.

22. The method of claim 21, wherein the multiple types of write operations comprise the SLC write operation and a multi-bit write operation that writes multiple bits per memory cell.

23. A non-transitory computer-readable medium storing code comprising instructions which, when executed by one or more processors of a memory system, cause the memory system to:
select, from a set of dynamic blocks, a subset of dynamic blocks as candidates for replacing other blocks, the set of dynamic blocks comprising blocks to which multiple types of write operations are permitted, each of the multiple types of write operations associated with different quantities of stored bits per memory cell;
determine whether a static block in a set of static blocks has satisfied a condition for replacement, the set of static blocks comprising blocks to which a single type of write operation is permitted; and
update, based at least in part on determining that the static block satisfies the condition for replacement, replacement information for tracking block replacements to indicate that a dynamic block in the subset of dynamic blocks is to be used instead of the static block for subsequent access operations.

24. The non-transitory computer-readable medium of claim 23, wherein instructions which cause the memory system to determine that the static block has satisfied the condition for replacement comprise instructions which, when executed by the memory system, cause the memory system to:
determine that a write fail status flag for the static block has been received, wherein the write fail status flag indicates that a write operation performed on the static block has failed.

25. The non-transitory computer-readable medium of claim 23, wherein instructions which cause the memory system to determine that the static block has satisfied the condition for replacement comprise instructions which, when executed by the memory system, cause the memory system to:
determine that an erase fail status flag for the static block has been received, wherein the erase fail status flag indicates that an erase operation performed on the static block has failed.
